(19) United States
(12) Patent Application Publication
(10) Pub. No.: US 2002/0163818 A1
(43) Pub. Date: Nov. 7, 2002

(54) Magnetic device and method of manufacture therefor

(76) Inventors: Mark D. Green, Eden Prairie, MN (US); Allen Frank Rozman, Richardson, TX (US)

Correspondence Address: HITT GAINES & BOISBRUN P.C., P.O. BOX 832570, RICHARDSON, TX, 75083, US

(21) Appl. No.: 09/800,052

(22) Filed: Mar. 5, 2001

(51) Int. Cl. H01L 29/82; H02M 3/335

(52) U.S. Cl. 363/20; 257/421

(57) ABSTRACT

A magnetic device, method of manufacture therefor and a power supply employing the magnetic device. In one embodiment, the magnetic device includes a metal substrate and a first dielectric layer formed over the metal substrate. The magnetic device further includes a first conductive layer formed over only a portion of the dielectric layer and a magnetic core mounted proximate the first conductive layer adapted to impart a desired magnetic property thereto.

### CROSS-REFERENCE TO RELATED APPLICATIONS AND PATENTS

This application is related to the following U.S. patents and applications:

| Reference No. | Title | Inventor(s) | Date |
|---|---|---|---|
| 08/908,887 | Methods of | Roessler, | Filed |
| ('887 | Manufacturing a | et al. | Aug. 8, |
| application) | Magnetic Device and | | 1997 |
| | Tool for Manufacturing | | |
| | the Same | | |
| 08/940,672 | Post-mountable Planar | Pitzele, et | Filed |
| ('672 | Magnetic Device and | al. | Sept. 30, |
| application) | Method of Manufacture | | 1997 |
| | Thereof | | |
| 09/045,217 | Power Magnetic Device | Pitzele, et | Filed |
| ('217 | Employing a Leadless | al. | Mar. 20, |
| application) | Connection to a Printed | | 1998 |
| | Circuit Board and | | |
| | Method of Manufacture | | |
| | Thereof | | |
| 09/184,753 | Lead-free Solder | Pilukaitis, | Filed |
| ('753 | Process for Printed | et al. | Nov. 2, |
| application) | Wiring Boards | | 1998 |
| 09/288,749 | Inter-substrate | Heinrich, | Filed |
| ('749 | Conductive Mount For a | et al. | April 8, |
| application) | Circuit Board, Circuit | | 1999 |
| | Board and Power | | |
| | Magnetic Device | | |
| | Employing The Same | | |
| 09/288,750 | Surface Mountable Power | Heinrich, | Filed |
| ('750 | Supply Module and | et al. | April 8, |
| application) | Method of Manufacture | | 1999 |
| | Therefor | | |
| 09/538,334 | Board Mounted Power | Chen, et | Filed |
| ('334 | Supply, Method of | al. | March 29, |
| application) | Manufacture therefore | | 2000 |
| | and Electronic Device | | |
| | Employing the Same | | |
| 5,303,138 | Low loss synchronous | Rozman | Issued |
| ('138 | rectifier for | | April 12, |
| patent) | application to clamped- | | 1994 |
| | mode power converters | | |
| 5,541,828 | Multiple Output | Rozman | Issued |
| ('828 | Converter with | | July 30, |
| patent) | Continuous Power | | 1996 |
| | Transfer to an Output | | |
| | and with Multiple | | |
| | Output Regulation | | |
| 5,588,848 | Low inductance surface | Law, et al. | Issued |
| ('848 | mount connectors for | | Dec. 31, |
| patent) | interconnecting circuit | | 1996 |
| | devices and method for | | |
| | using same | | |
| 5,590,032 | Self-synchronized drive | Bowman, et | Issued |
| ('032 | circuit for a | al. | Dec. 31, |
| patent) | synchronous rectifier | | 1996 |
| | in a clamped-mode power | | |
| | converter | | |
| 5,625,541 | Low loss synchronous | Rozman | Issued |
| ('541 | rectifier for | | April 29, |
| patent) | application to clamped- | | 1997 |
| | mode power converters | | |
| 5,724,016 | Power Magnetic Device | Roessler, | Issued |
| ('016 | Employing a | et al. | Mar. 3, |
| patent) | Compression-mounted | | 1998 |
| | Lead to a Printed | | |
| | Circuit Board | | |
| 5,750,935 | Mounting Device for | Stevens | Issued |
| ('935 | Attaching a Component | | May 12, |
| patent) | Through an Aperture in | | 1998 |
| | a Circuit Board | | |
| 5,787,569 | Encapsulated Package | Lotfi, et | Issued |
| ('569 | for Power Magnetic | al. | Aug. 4, |
| patent) | Devices and Method of | | 1998 |
| | Manufacture Therefor | | |
| 5,835,350 | Encapsulated, | Stevens | Issued |
| ('530 | Board-mountable Power | | Nov. 10, |
| patent) | Supply and Method of | | 1998 |
| | Manufacture Therefor | | |
| 5,926,373 | Encapsulated, Board- | Stevens | Issued |
| ('373 | mountable Power Supply | | July 20, |
| patent) | and Method of | | 1999 |
| | Manufacture Therefor | | |
| 5,992,005 | Method of Manufacturing | Roessler, | Issued |
| ('005 | a Power Magnetic Device | et al. | Nov. 30, |
| patent) | | | 1999 |
| 6,005,773 | Board-mountable Power | Rozman, et | Issued |
| ('773 | Supply Module | al. | Dec. 21, |
| patent) | | | 1999 |

The above-listed applications and patents are commonly assigned with the present invention and are incorporated herein by reference as if reproduced herein in their entirety.

### TECHNICAL FIELD OF THE INVENTION

The present invention is directed, in general, to electronic devices and, more specifically, to a magnetic device, method of manufacture therefor and a power supply employing the magnetic device.

### BACKGROUND OF THE INVENTION

A pervasive change in the design and assembly of electronic devices that has been occurring over the last several years, and one that continues to occur, is the development of more compact and, at the same time, more complex electronic devices. Because customers continue to demand smaller and more complex electronic devices, designers of such electronic devices must be more innovative in their product design and configuration.

One of the essential circuits found in many electronic devices is a power supply. The power supplies typically receive electrical power from an external power source and condition the power to meet the requirements of the components of the electronic device. For example, many electronic devices require DC power to operate. The external power source, however, may only provide AC power. The power supply is therefore required to convert the AC power to the DC power to operate the components of the electronic device.

The use of more efficient power supplies is one way that the electronic devices can be made more compact. This must be done while preserving the functional capabilities of the power supply. If a power supply can be made smaller and more efficient, more space on the circuit boards of the electronic device may be made available for other electronic components or, if additional components are not required, the size and weight of the circuit boards and, accordingly, the electronic device itself, can be reduced.

Board-mounted power supplies currently being used in many electronic devices frequently require a transformer to convert AC power to DC power. In one conventional approach, the transformer is physically mounted on a surface of the circuit board and projects into the adjacent space, thereby transferring generated heat to the surrounding air in the environment of the circuit board. While functional, this configuration places a major heat generating device on one side of the board. Alternatively, the transformer may be constructed by building up the transformer windings on either side of the circuit board, and placing the core physically about the windings with the core centered on the circuit board.

Traditionally, board mounted power supplies have not been without problems. For example, it is in the very nature of power supplies that they generate a considerable amount of heat. Full load operation at 85° C. ambient air is becoming the norm as systems become more compact. Conventional circuit boards, such as a multi-layer FR-4 board manufactured by Photocircuits Corporation of Glen Cove, N.Y., have difficulty dissipating the heat because of poor thermal conductivity. Alternatively, insulated metal substrate boards, with improved thermal conductivity, have been used except presently there is no configuration for integrating components, such as magnetic devices (e.g., a transformer), on to the board to take proper advantage of the such attributes. Therefore, discrete magnetic devices have been employed with power supplies constructed on the insulated metal substrate boards.

Accordingly, what is needed in the art is a magnetic device configuration that may be integrated into a circuit board such as an insulated metal substrate board.

### SUMMARY OF THE INVENTION

To address the above-discussed deficiencies of the prior art, the present invention provides a magnetic device, method of manufacture therefor and a power supply employing the magnetic device. In one embodiment, the magnetic device includes a metal substrate and a first dielectric layer formed over the metal substrate. The magnetic device further includes a first conductive layer formed over only a portion of the dielectric layer and a magnetic core mounted proximate the first conductive layer adapted to impart a desired magnetic property thereto.

The present invention introduces, in one aspect, a magnetic device that may be formed as an integral part of an insulated metal substrate. As a result, the magnetic device may assume a reduced overall profile.

The foregoing has outlined, rather broadly, preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention in its broadest form.

### BRIEF DESCRIPTION OF THE DRAWINGS

The invention is best understood from the following detailed description when read with the accompanying FIGURES. It is emphasized that in accordance with the standard practice in the electronics industry, various features may not be drawn to scale. In fact, the dimensions of the various features may be arbitrarily increased or reduced for clarity of discussion. Reference is now made to the following descriptions taken in conjunction with the accompanying drawings, in which:

FIG. 1 illustrates an isometric view of an embodiment of an electrical device constructed according to the principles of the present invention;

FIG. 2 illustrates an exploded isometric view of an embodiment of a multilayer subassembly constructed according to the principles of the present invention;

FIG. 3A illustrates an exploded isometric view of an embodiment of a magnetic device constructed according to the principles of the present invention;

FIG. 3B illustrates a partial sectional view of the magnetic device of FIG. 3A along a plane 3B-3B;

FIG. 4 illustrates an isometric view of an embodiment of a power supply constructed according to the principles of the present invention; and

FIG. 5 illustrates a schematic diagram of an embodiment of a power supply constructed according to the principles of the present invention.

### DETAILED DESCRIPTION

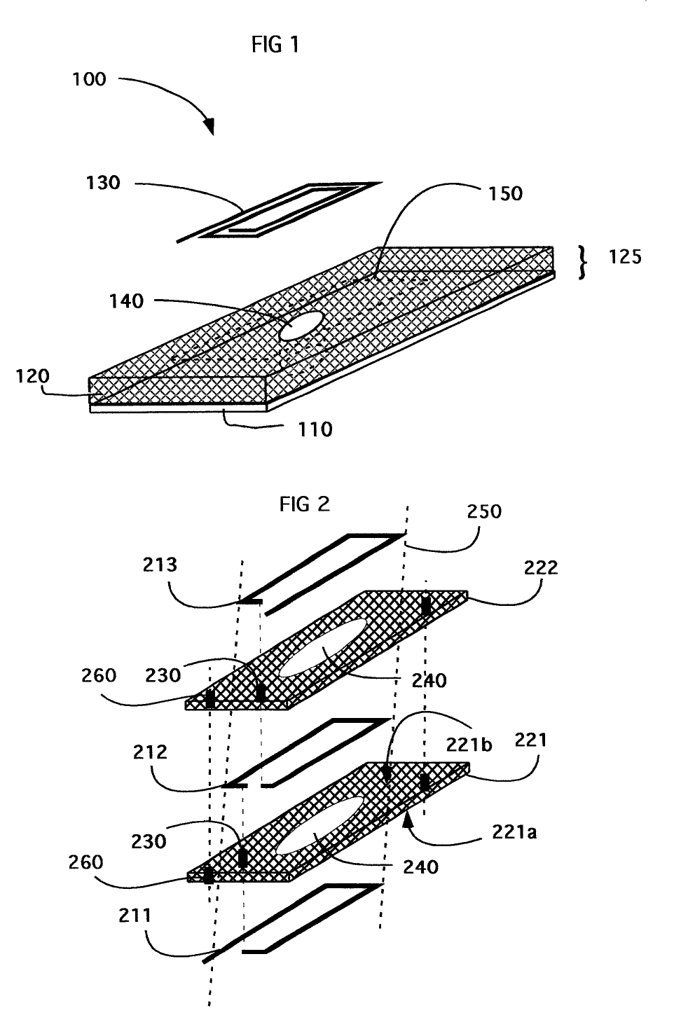

Referring initially to FIG. 1, illustrated is an isometric view of an embodiment of an electrical device 100 constructed according to the principles of the present invention. The electrical device 100 includes a metal substrate 110, a dielectric layer 120, a conductive layer 130 and an aperture 140. The dielectric layer 120 is formed over and, in the illustrated embodiment, completely covers the metal substrate 110. However, those skilled in the art will realize that the dielectric layer 120 need not necessarily cover the entire metal substrate 110.

The metal substrate 110 and dielectric layer 120 form an insulated metal substrate 125. The insulated metal substrate 125 is thermally conductive with the metal substrate 110 formed from a metal sheet material and the dielectric layer 120 formed from a thermally conductive insulated adhesive material. The metal sheet material is selected based upon the coefficient of thermal expansion (CTE), thermal conductivity, heat capacity, cost, and other criteria specific to the end application. The metal substrate 110 may be treated with a surface treatment to promote adequate adhesion between the metal substrate 110 and the dielectric layer 120. In an exemplary embodiment, the insulated metal substrate 125 may be an insulated metal substrate provided by the Bergquist Company of Chanhassen, Minnesota as disclosed, in pertinent part, in U.S. Pat. No. 4,810,563, entitled “Thermally Conductive, Electrically Insulative Laminate,” by David G. DeGree, et al., issued Mar. 7, 1989, which is incorporated herein by reference. In accordance therewith, the thermally conductive insulated adhesive material may be a Thermal Clad® thermally conductive dielectric adhesive designed by the Bergquist Company.

The dielectric layer 120, also being an adhesive in the present embodiment, physically bonds the metal substrate 110 to the conductive layer 130 as well as insulating the metal substrate 110 from the conductive layer 130. The conductive layer 130 may be formed from any suitable conductive material (e.g., aluminum, copper, gold) and is formed over only a portion (i.e., area 150) of the dielectric layer 120. In the illustrated embodiment, the conductive layer 130 is formed as a trace proximate the aperture 140. Of course, the conductive layer 130 may take any required form. The aperture 140 is formed in and passes through both the dielectric layer 120 and the metal substrate 110 proximate the area 150 of the dielectric layer 120. Those skilled in the art will recognize that the conductive layer 130 and aperture 140 form a two-turn air coil, a basic form of an electrical inductive device. Of course, single turns or additional turns may be formed as needed. Additionally, a magnetic material may also be used as a magnetic core thereby forming a solenoid.

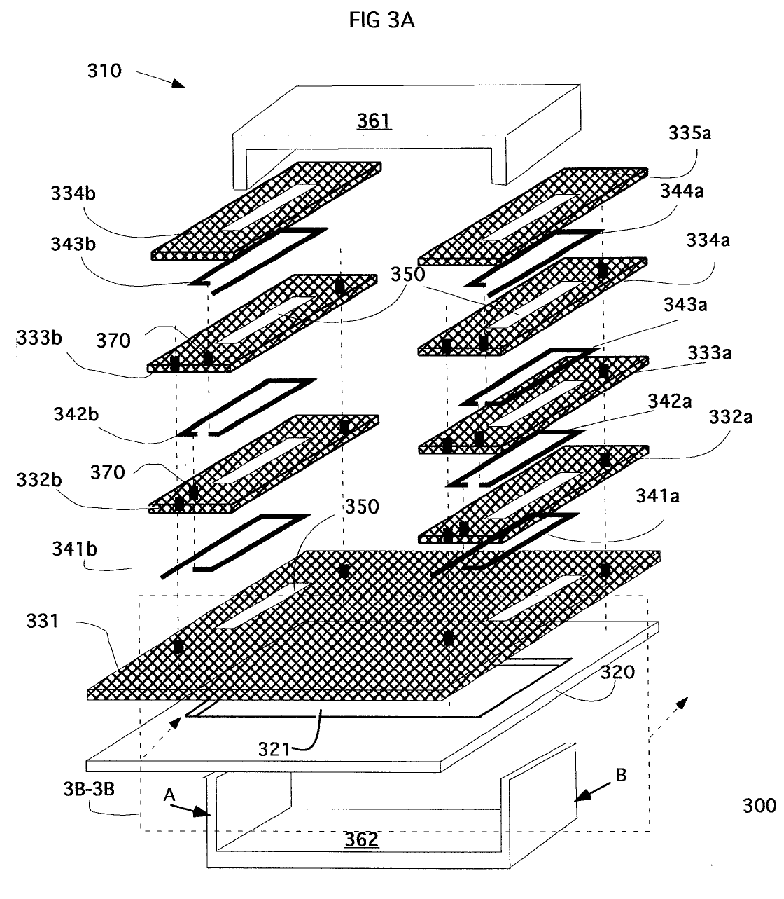

Turning now to FIG. 2, illustrated is an exploded isometric view of an embodiment of a multilayer subassembly constructed according to the principles of the present invention. The multilayer subassembly includes first, second, and third conductive layers 211, 212, 213, first and second dielectric layers 221, 222, conductive vias (collectively designated 230) and apertures (collectively designated 240).

The first and second conductive layers 211, 212 may be formed of a metal foil of appropriately selected weight about two faces 221a, 221b of the first dielectric layer 221 using external registration 250 or registration vias 260. Those skilled in the art are familiar with the registration of layered electrical components. Exposed faces of the first, second, and third conductive layers 211, 212, 213 are conditioned as required. A bond is formed between the respective layers in a manner as described in DeGree, et al. The conductive vias 230 may be formed by drilling or routing with the addition of electrical connectivity via isolation material (not shown), if necessary.

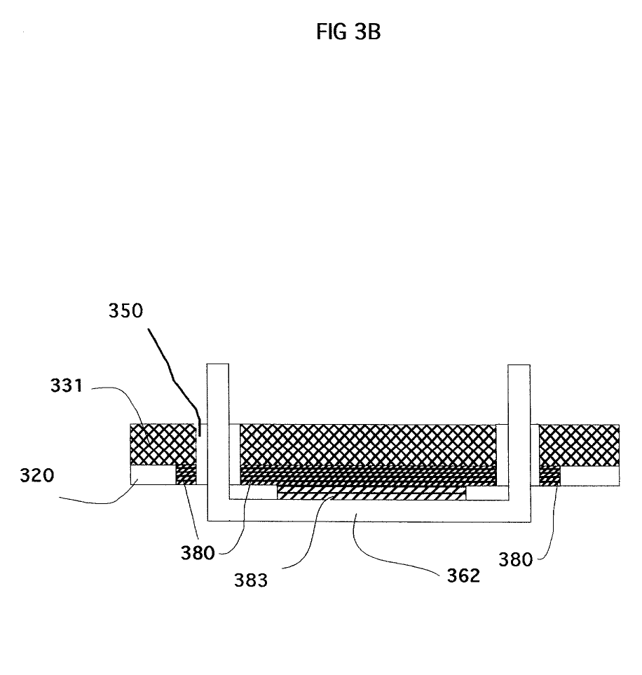

Turning now to FIG. 3A, illustrated is an exploded isometric view of an embodiment of a magnetic device 310 constructed according to the principles of the present invention. The magnetic device 310 includes a metal substrate 320, a first dielectric layer 331, first conductive layers or windings 341a, 341b, second dielectric layers 332a, 332b, second conductive layers or windings 342a, 342b, third dielectric layers 333a, 333b, third conductive layers or windings 343a, 343b, fourth dielectric layers 334a, 334b, a fourth conductive layer or winding 344a, a fifth dielectric layer 335a, apertures (collectively designated 350), first and second magnetic core halves 361, 362 (forming a magnetic core), and conductive vias (collectively designated 370). The first and second magnetic core halves 361, 362 are placed through in the apertures 350 and retained therein. The metal substrate 320 has an extended aperture 321 between the apertures 350 in the first dielectric layer 331 so as to prevent core half 362 from shorting between a pole A and a pole B of the magnetic core 361, 362. Of course, other configurations including insulated standoffs, etc., may also be incorporated in the core halves 361, 362 to accomplish the same objective. Those skilled in the art are familiar with such standoffs.

In the illustrated embodiment, the magnetic device 310 is a transformer having four windings 341a, 342a, 343a, 344a about one pole A of the magnetic core 361, 362 and three windings 341b, 342b, 343b about the other pole B of the magnetic core 361, 362. Fourth dielectric layer 334b and fifth dielectric layer 335a assure that magnetic core half 361 does not create a short between pole A and pole B. Thus, with the present invention, the magnetic device 310 may be constructed as an integral part of an insulated metal substrate having any desired number of windings per pole of the core. Of course, an application for the magnetic device 310 is in a power supply and, therefore, the windings 341a, 342a, 343a, 344a about the one pole A of the magnetic core 361, 362 and the windings 341b, 342b, 343b about the other pole B of the magnetic core 361, 362 may be connected to separate stages of the power supply. Those skilled in the art are familiar with the use of transformers in power supplies.

Turning now to FIG. 3B, illustrated is a partial sectional view of the magnetic device 310 of FIG. 3A along a plane 3B-3B. The sectional view illustrates the metal substrate 320, the first dielectric layer 331, the apertures 350, the second magnetic core half 362 and relieved areas (collectively designated 380). The relieved areas 380 are removed from the metal substrate 320 proximate the apertures 350 to prevent shorting by the second magnetic core half 362. An additional insulative spacer 383 may also be employed as shown.

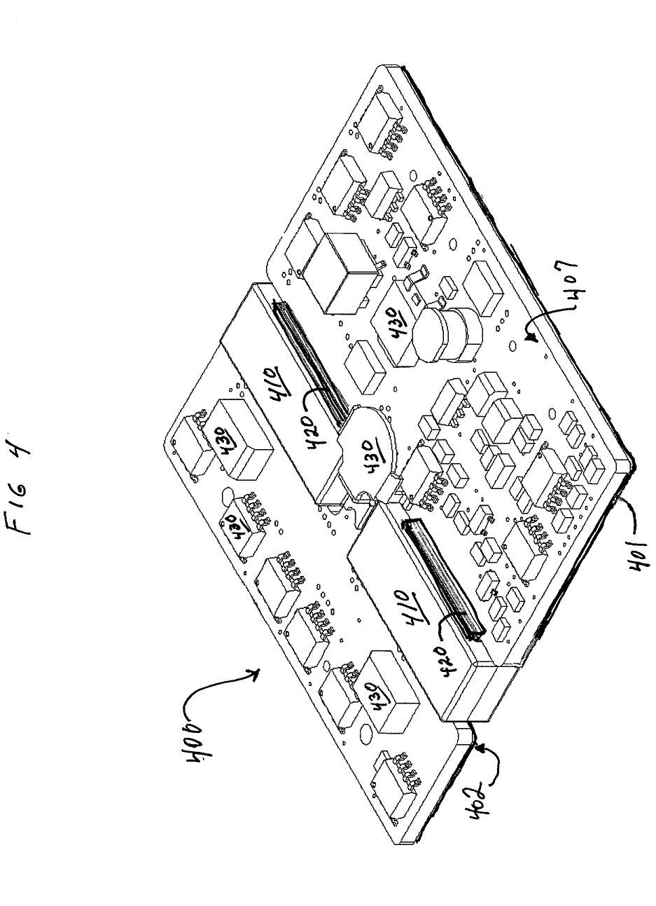

Referring now to FIG. 4, illustrated is an embodiment of a power supply constructed according to the principles of the present invention. The power supply is constructed on a circuit board 400 having multi-layered magnetic devices 410 constructed according to the principles of the present invention on only portions 420 of the circuit board 400. It should be noted that the circuit board 400 is primarily a conventional circuit board having a metal layer 401 that extends entirely across a surface 402 of the circuit board 400. Of course, that metal layer 401 need not, in its finished state, be contiguous across the circuit board 400, but may be formed by masking and etching into simple or complex traces that interconnect components, some representative components designated 430, on an opposing surface 407 thereof. One who is skilled in the art is familiar with the formation of interconnecting traces on printed circuit boards.

Only portions 420 of the circuit board 400 are multi-layered having alternating conductive and dielectric layers as described above. The portions 420 may have a plurality of layers as required for a particular application while the rest of the circuit board 400 has only a single layer. Of course, provisions to avoid shorting by the cores as discussed with respect to FIGS. 3A and 3B should be addressed in any such design.

Referring now to the preceding FIGURES in general, a method of manufacturing will hereinafter be described. To manufacture a multi-layered magnetic device, a metal sheet material acting as a metal substrate is selected based on its coefficient of thermal expansion, thermal conductivity, heat capacity, cost, and other appropriate criteria in accordance with the end application. Surfaces of the metal sheet material are given a surface treatment to promote adequate adhesion between the metal sheet material and a dielectric layer such as a thermally conductive insulated adhesive material. The dielectric layer is bonded to the metal substrate in a manner as described in Degree, et al.

Subassemblies formed of alternating conductive layers (e.g., windings) and dielectric layers are progressively formed together using the bonding process and conventional masking, developing and etching techniques as required until the desired number of conductive layers has been achieved. Interconnecting conducting vias and the metal interconnects (not shown) filling them between conducting layers are formed conventionally as the subassemblies are manufactured. A plurality of relieved areas are concurrently formed in a similar manner by masking and etching.

A pair of apertures are then formed in the respective layers of the subassemblies and the metal substrate. If necessary, additional registration vias or conductive vias may be drilled during the winding build-up. Using a layer registration system as above along with heat and pressure, the conductive layers are mated to the dielectric layers about the apertures therethrough. When appropriate, a plurality of the subassemblies may be formed to the required layers/thickness on a single sheet and then separated by cutting or routing. These subassemblies are then affixed to the metal substrate using heat and pressure in accordance with Degree, et al. Finally, first and second magnetic core halves are inserted into the apertures and fastened to each other with an appropriate adhesive. Final connections to the contacts for each winding and the remainder of the circuit are formed by conventional means.

Thus, a magnetic device and method of manufacturing a multi-layered magnetic device integrally on an insulated metal substrate board has been described. It should be clear to those skilled in the art that the present invention, may be used to manufacture any of the variety of magnetic devices (e.g., transformers, inductors, etc.) integrally with an insulated metal substrate.

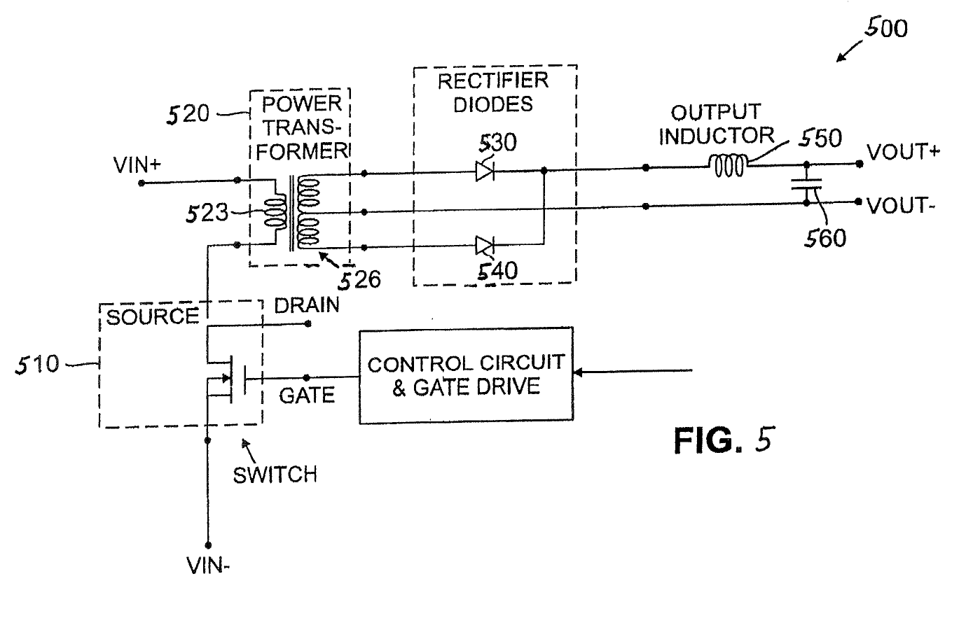

Turning now to FIG. 5, illustrated is a schematic diagram of an embodiment of a power supply 500 constructed according to the principles of the present invention. The power supply 500 includes a power train having a conversion stage including a power switching device 510 for receiving input electrical power V_{IN} and producing therefrom switched electrical power. The power supply 500 further includes a filter stage (including an output inductor 550 and output capacitor 560) for filtering the switched electrical power to produce output electrical power (represented as an output voltage V_{OUT}). The power supply 500 still further includes a transformer 520, having a primary winding 523 and a secondary winding 526) and a rectification stage (including rectifying diodes 520, 530) coupled between the power conversion stage and the filter stage. The transformer 520 is constructed according to the principles of the present invention as previously described. Of course, the magnetic device constructed according to the principles of the present may be employed in other electronic circuits such as transmission circuits.

For a better understanding of power electronics including power supplies and conversion technologies see “Principles of Power Electronics,” by J. G. Kassakian, M. F. Schlecht and G. C. Verghese, Addison-Wesley (1991). For a better understanding of magnetic devices and construction techniques therefor see “Printed Circuits Handbook,” by Clyde Coombs, Jr., McGraw Hill Book Co., 4th Edition (1995). The aforementioned references are incorporated herein by reference.

Although the present invention has been described in detail, those skilled in the art should understand that they can make various changes, substitutions and alterations herein without departing from the spirit and scope of the invention in its broadest form.

What is claimed is:

1. A magnetic device, comprising:
a metal substrate;
a first dielectric layer formed over said metal substrate;
a first conductive layer formed over only a portion of said dielectric layer; and
a magnetic core mounted proximate said first conductive layer adapted to impart a desired magnetic property thereto.

2. The magnetic device as recited in claim 1 further comprising a second dielectric layer formed over said first conductive layer.

3. The magnetic device as recited in claim 2 further comprising a second conductive layer formed over said second dielectric layer.

4. The magnetic device as recited in claim 3 further comprising a conductive via through said first and second conductive layers and said second dielectric layer.

5. The magnetic device as recited in claim 3 wherein said magnetic device is a transformer.

6. The magnetic device as recited in claim 1 wherein said first conductive layer is composed of aluminum or copper.

7. The magnetic device as recited in claim 1 further comprising an aperture through said metal substrate, said first dielectric layer and said first conductive layer, said magnetic core being positioned through said aperture.

8. A method of manufacturing a magnetic device, comprising:
providing a metal substrate;
forming a first dielectric layer over said metal substrate;
forming a first conductive layer over only a portion of said dielectric layer; and
mounting a magnetic core proximate said first conductive layer adapted to impart a desired magnetic property thereto.

9. The method as recited in claim 8 further comprising forming a second dielectric layer over said first conductive layer.

10. The method as recited in claim 9 further comprising forming a second conductive layer over said second dielectric layer.

11. The method as recited in claim 10 further comprising forming a conductive via through said first and second conductive layers and said second dielectric layer.

12. The method as recited in claim 10 wherein said magnetic device is a transformer.

13. The method as recited in claim 8 wherein said first conductive layer is composed of aluminum or copper.

14. The method as recited in claim 8 further comprising forming an aperture through said metal substrate, said first dielectric layer and said first conductive layer, said magnetic core being positioned through said aperture.

15. A magnetic device, comprising:
an insulated metal substrate;
a plurality of interleaved conductive layers and dielectric layers integrally formed over only a portion of said insulated metal substrate, said portion having a different number of layers than other portions of said insulated metal substrate; and
a magnetic core mounted proximate said plurality of conductive and dielectric layers adapted to impart a desired magnetic property to said conductive layers.

16. The magnetic device as recited in claim 15 wherein said insulated metal substrate comprises an adhesive material.

17. The magnetic device as recited in claim 15 further comprising a conductive via through said plurality of conductive and dielectric layers.

18. The magnetic device as recited in claim 15 wherein said conductive layers are composed of aluminum or copper.

19. The magnetic device as recited in claim 15 wherein said insulated metal substrate and said plurality of interleaved conductive layers and dielectric layers comprise an aperture therethrough, said magnetic core being positioned within said aperture.

20. The magnetic device as recited in claim 15 wherein said magnetic device is a transformer.

21. A power supply, comprising:
an insulated metal substrate;
a power train having a power switching device coupled to said insulated metal substrate at a first location;
a rectification stage having at least one rectifying device coupled to said insulated metal substrate at a second location; and
a transformer, interposed between said power train and said rectification stage, including:
a plurality of interleaved conductive layers and dielectric layers integrally formed over said insulated metal substrate at a third location, and
a magnetic core mounted proximate said plurality of conductive and dielectric layers adapted to impart a desired magnetic property to said conductive layers.

22. The power supply as recited in claim 21 further comprising a conductive via through said plurality of conductive and dielectric layers.

23. The power supply as recited in claim 21 wherein said conductive layers are composed of aluminum or copper.

24. The power supply as recited in claim 21 wherein said insulated metal substrate and said plurality of interleaved conductive layers and dielectric layers comprise an aperture therethrough, said magnetic core being positioned within said aperture.

25. The power supply as recited in claim 21 further comprising a filter stage having an output inductor and output capacitor coupled to said insulated metal substrate at a fourth location.
